(19) United States
(12) Patent Application Publication
(10) Pub. No.: US 2009/0308740 A1
(43) Pub. Date: Dec. 17, 2009

(54) CoCrPt Base Sputtering Target and Production Process for the Same

(75) Inventors: Kazuteru Kato, Omuta-shi (JP); Nobukazu Hayashi, Omuta-shi (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD., Tokyo (JP)

(21) Appl. No.: 12/306,427

(22) PCT Filed: Dec. 26, 2007
(86) PCT No.: PCT/JP2007/075031

§ 371 Date: Dec. 23, 2008

(30) Foreign Application Priority Data
Jan. 4, 2007 (JP) 2007-000165

(51) Int. Cl. C23C 14/34

(52) U.S. Cl. 204/298.13

(57) ABSTRACT

An object of the present invention is to provide a CoCrPt base sputtering target in which high chromium-containing particles containing a chromium atom at a high concentration unevenly distributed in the above sputtering target are reduced in a size and a production amount to thereby enhance a uniformity of the target and inhibit nodules or acing from being caused and which has the targeted composition ratio.

The CoCrPt base sputtering target of the present invention is a sputtering target containing cobalt, chromium, ceramics and platinum, and it is characterized by that high chromium-containing particles containing a chromium atom at a high concentration which are unevenly distributed in the above sputtering target have a maximum full diameter of 40 μm or less.

### BACKGROUND OF THE INVENTION

The present invention relates to a CoCrPt base sputtering target containing cobalt, chromium, ceramics and platinum and a production process for the same.

### RELATED ART

A magnetic recording film prepared by dispersing oxides in an alloy comprising cobalt-chromium-platinum which can provide a high coercive force and a low medium noise property has so far been used in many cases for vertical magnetic recording media. The above magnetic recording film is produced by using a CoCrPt base sputtering target containing oxides to carry out sputtering on an alloy comprising cobalt-chromium-platinum.

In recent years, magnetic recording media in which a coercive force is enhanced further more and which is reduced in medium noises are required, and therefore researches for pulverizing further finely crystal particles constituting a magnetic recording film and dispersing a non-magnetic phase of oxides have been promoted.

In the situation described above, disclosed in a patent document 1 is a process in which alloy powder comprising an alloy of metal elements such as chromium and platinum with cobalt is prepared by a rapid solidification method and then subjected to mechanical alloying with ceramic powder to prepare composite powder and in which it is then subjected to hot-pressing to thereby produce a CoCrPt base sputtering target. According to the above process, a target having a crystal composition in which an alloy phase and a ceramic phase are homogeneously dispersed can be produced, and a magnetic recording film obtained by sputtering the above target is excellent in various characteristics.

However, a high chromium-containing particle containing a chromium atom at a high concentration, a so-called chromium-rich phase is unevenly distributed in the CoCrPt base sputtering target described above. The presence of such high chromium-containing particles in the target makes it easy to allow a large part of the particles to drop from the target surface (surface used for sputtering) during sputtering, and the dropped particles lead to bringing about arcing. Also, this dropping results in producing nodules. Further, the high chromium-containing particles dropped are not only likely to be sputtered as they are to provide a magnetic recording film which is lacking in a uniformity of a chromium concentration but also likely to be scattered to produce a large difference between a composition of the sputtering target and a composition of the resulting magnetic recording film, whereby the characteristics of the magnetic recording film are likely to be varied.

On the other hand, when preparing a CoCrPt base sputtering target containing platinum, a production process for the same in which a yield of platinum is high is desired since platinum itself is expensive.

However, a yield of platinum can not sufficiently be enhanced in the production process disclosed in the patent document 1.

Patent document 1: Japanese Patent Publication No. 3816595

### DISCLOSURE OF THE INVENTION

If a CoCrPt base target which is reduced in high chromium-containing particles containing a chromium atom at a high concentration unevenly distributed in the target, a so-called chromium-rich phase and which has a higher uniformity is not prepared, it is difficult to prevent nodules and arcing in sputtering which originate in the above high chromium-containing particles from being caused. The presence and the reduction of the high chromium-containing particles described above have not so far been sufficiently investigated.

Accordingly, an object of the present invention is to provide a CoCrPt base sputtering target containing cobalt, chromium, ceramics and platinum in which high chromium-containing particles containing a chromium atom at a high concentration unevenly distributed in the above sputtering target are reduced in a size and a production amount to thereby enhance a uniformity of the target and inhibit nodules or acing from being caused and which has the targeted composition ratio.

Further, another object of the present invention is to provide a production process for a CoCrPt base sputtering target in which not only the target described above can be produced but also a yield of platinum can be enhanced.

The CoCrPt base sputtering target of the present invention is characterized by containing cobalt, chromium, ceramics and platinum, wherein high chromium-containing particles containing a chromium atom at a high concentration which are unevenly distributed in the above sputtering target have a maximum full diameter of 40 μm or less.

In the CoCrPt base sputtering target of the present invention, high chromium-containing particles having a full diameter of 15 μm or more account preferably for 20 particles or less in a viewing field of 0.6×0.5 mm² measured on the surface of the above sputtering target under a scanning type analytical electron microscope.

The production process of the present invention for a CoCrPt base sputtering target includes two processes of a first process and a second process.

Among the production processes of the present invention for a CoCrPt base sputtering target, the first process is characterized by comprising:

an A step in which an alloy comprising cobalt and chromium is atomized and then pulverized to thereby obtain a powder (1),
a B step in which cobalt and ceramics are subjected to mechanical alloying to thereby obtain a powder (2),
a C step in which the powder (1) and the powder (2) are mixed with platinum to obtain a powder (3) and
a D step in which the powder (3) is calcined.

The C step described above may be a step in which the powder (1) and the powder (2) are mixed with platinum and cobalt to obtain the powder (3).

The D step described above may be a step in which the powder (3) is calcined by pressure sintering.

Further, an E step in which the powder (3) is sized may be provided between the C step and the D step described above.

A chromium-containing powder having a microtrac particle diameter (D₉₀) of 50 μm or less may be used as the powder (1) in the A step described above.

Among the production processes of the present invention for a CoCrPt base sputtering target, the second process is characterized by comprising:

an F step in which an alloy of cobalt and chromium and ceramics are subjected to mechanical alloying to thereby obtain a powder (4),
a G step in which the powder (4) is mixed with platinum to obtain a powder (5) and
a H step in which the powder (5) is calcined.

The G step described above may be a step in which the powder (4) is mixed with platinum and cobalt to obtain the powder (5).

The H step described above may be a step in which the powder (D) is calcined by pressure sintering.

Further, an I step in which the powder (5) is sized may be provided between the G step and the H step described above.

A chromium-containing powder having a microtrac particle diameter (D₉₀) of 50 μm or less may be used as the powder (4) in the F step described above.

According to the CoCrPt base sputtering target of the present invention, high chromium-containing particles containing a chromium atom at a high concentration which are unevenly distributed in the above sputtering target are reduced in a number, and therefore the target is excellent in uniformity. In addition thereto, the high chromium-containing particles which drop from the surface of the target in sputtering can be reduced as well in a number, and nodules and arcing can be inhibited from being brought about.

Also, in the CoCrPt base sputtering target of the present invention, the high chromium-containing particles are reduced in a number, and therefore a magnetic recording film in which a composition ratio of chromium is inhibited from being varied and in which a dispersibility of a coercive force is reduced can be obtained by a sputtering method.

Further, according to the production processes of the present invention, not only the CoCrPt base sputtering target described above can be obtained, but also the above sputtering target can be produced without passing through a step for atomizing platinum, and therefore a yield of platinum in the production step can be enhanced as well.

### BRIEF DESCRIPTIONS OF THE DRAWINGS

FIG. 1 is a picture showing ceramics (SiO²) by a black color on the surface of the CoCrPt base sputtering target containing cobalt, chromium, ceramics and platinum which is observed under a scanning type analytical electron microscope.

FIG. 2 is a picture showing high chromium-containing particles by a white color on the surface of the CoCrPt base sputtering target containing cobalt, chromium, ceramics and platinum which is observed under the scanning type analytical electron microscope.

FIG. 3 is a picture showing schematically the high chromium-containing particles in FIG. 2.

### EXPLANATION OF THE CODE

10 Full diameter of the high chromium-containing particles

### BEST MODE FOR CARRYING OUT THE INVENTION

The CoCrPt base sputtering target of the present invention and the production process for the same shall specifically be explained below.

### <CoCrPt Base Sputtering Target>

The CoCrPt base sputtering target of the present invention (hereinafter referred to as the sputtering target of the present invention) contains cobalt, chromium, ceramics and platinum. The sputtering target of the present invention contains usually chromium of 1 to 40 mole %, preferably 1 to 30 mole % and more preferably 1 to 20 mole %, platinum of 1 to 40 mole %, preferably 5 to 30 mole % and more preferably 5 to 20 mole % and ceramics of 0.01 to 40 mole %, preferably 0.01 to 30 mole % and more preferably 0.01 to 20 mole % base on 100 mole % of the above target, and the balance is cobalt. Ceramics is at least one selected from the group consisting of silicon dioxide, titanium dioxide, tantalum pentaoxide, Al₂O₃, MgO, CaO, ZrO₂, B₂O₃, Sm₂O₃, HfO₂ and Gd₂O₃, and among them, silicon dioxide is preferred. Other elements may be contained in the balance as long as the effects of the present invention are not damaged. They include, for example, tantalum, niobium, neodymium and the like.

In the CoCrPt base sputtering target, a so-called chromium-rich phase in which high chromium-containing particles containing a chromium atom at a high concentration are unevenly distributed is usually present, that is, a so-called chromium-rich phase is present. In the sputtering target of the present invention, a size or a present number of the above high chromium-containing particles is controlled.

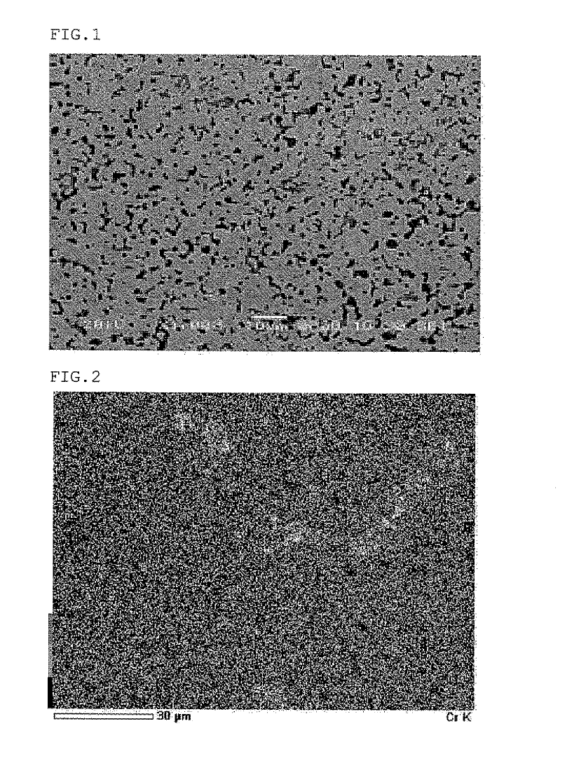

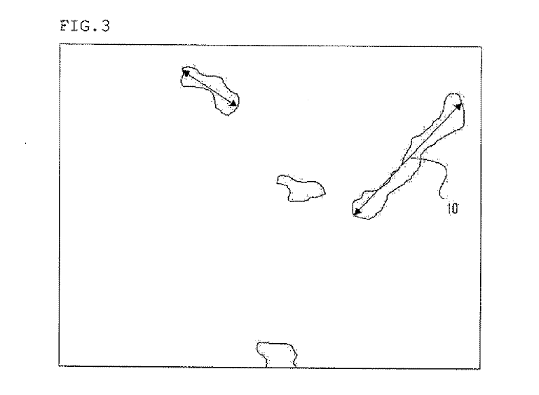

FIG. 1 and FIG. 2 are pictures obtained by observing the surface of the CoCrPt base sputtering target containing cobalt, chromium, ceramics and platinum under the scanning type analytical electron microscope. In FIG. 1, silicon dioxide which is ceramics is shown by a black color, and in FIG. 2, a chromium-rich phase is shown by a white color. It can be found from FIG. 2 that the high chromium-containing particles shown by a white color are unevenly distributed.

In the present specification, “the high chromium-containing particles are unevenly distributed” means an area in which a chromium concentration (atom %) is higher by 0.6 atom % or more than a concentration of chromium blended in preparing the target, wherein an area shown by a white color in FIG. 2 is magnified by 10000 times to carry out simple quantitative face analysis of chromium in a viewing field of 20×10 μm.

FIG. 3 is a picture showing schematically the high chromium-containing particles in FIG. 2. In the present specification, “a full diameter” of the high chromium-containing particles means the longest diameter in an area occupied by the high chromium-containing particles, and to be specific, it is a diameter shown by 10 in FIG. 3. Accordingly, “a maximum full diameter” means a full diameter showing the largest value among the full diameters of plural high chromium-containing particles. In the present specification, the surface of the target was observed on the measuring conditions of an accelerating voltage of 20 kV, a counting rate of 25% and a measuring time of 60 seconds by means of the scanning type analytical electron microscope described above to distinguish the high chromium-containing particles.

In the sputtering target of the present invention, a full diameter showing the largest value among the full diameters of plural high chromium-containing particles unevenly distributed in the target is 40 μm or less, preferably 30 μm or less and more preferably 20 μm or less. A lower limit value of the above full diameter shall not specifically be restricted, and the lower limit which can be distinguished by the discriminant method described above is usually 15 μm.

In general, when high chromium-containing particles are present in a target, a large part of the particles is liable to drop from the surface of the target in sputtering, and the dropped particles cause bringing about arcing. The larger the size of the high chromium-containing particles is, the higher the possibility at which they drop is. If the particles drop as described above, nodules are highly probable to be produced in the target. Further, if the dropped high chromium-containing particles are sputtered as they are, a magnetic recording film in which a chromium concentration is uneven is likely to be obtained, and a large difference is apt to be produced between a composition ratio of the sputtering target and a composition ratio of the resulting magnetic recording film due to scattering of the dropped high chromium-containing particles.

In the present invention, a full diameter showing the largest value among the full diameters of plural high chromium-containing particles unevenly distributed in the target is 40 μm or less, and therefore the high chromium-containing particles can be controlled to a fixed size or less to reduce generation of nodules or arcing in sputtering. Further, controlling of the high chromium-containing particles to a fixed size or less as described above makes it possible to obtain the CoCrPt base sputtering target having a higher uniformity.

In the sputtering target of the present invention, the number of the high chromium-containing particles having a full diameter of 15 μm or more on the surface of the target among plural high chromium-containing particles unevenly distributed in the target is 20 particles or less, preferably 10 particles or less and more preferably 1 particle or less in a viewing field of 0.6×0.5 mm² measured under the scanning type analytical electron microscope. A lower limit value of the above number of the particles shall not specifically be restricted, and it is usually 0.2 particle (one particle in a viewing field of 0.6×0.5 mm²×5) or more, preferably 0.01 particle (one particle in a viewing field of 0.6×0.5 mm²×10) or more.

As described above, not only a size of the high chromium-containing particles unevenly distributed in the target is controlled to a fixed size or less, but also the number of the high chromium-containing particles having a fixed size or more is reduced as well, whereby a lot of excessive high chromium-containing particles can be prevented from being present in the target, and therefore generation of nodules or arcing in sputtering can be reduced further more. Further, reduction of the number of the high chromium-containing particles unevenly distributed in the target makes it possible to obtain the CoCrPt base sputtering target having a higher uniformity.

The CoCrPt base sputtering target of the present invention can be produced by a production process described later.

### <Magnetic Recording Film>

A magnetic recording film can be obtained by sputtering the CoCrPt base sputtering target of the present invention. Usually, a DC magnetron sputtering method or an RF magnetron sputtering method is suitably used as the sputtering method. The film thickness shall not specifically be restricted, and it is usually 5 to 100 nm, suitably 5 to 20 nm.

The magnetic recording film thus obtained can contain cobalt, chromium, ceramics and platinum in a composition ratio of about 95% or more which is the target. The above magnetic recording film is obtained from the sputtering target of the present invention which is reduced in a size and a production number of the high chromium-containing particles, and therefore it has a high uniformity and can sufficiently exhibit specific magnetic characteristics. Further, the above magnetic recording film is excellent in a perpendicular magnetic anisotropy and a vertical coercive force, and therefore it can suitably be used as a vertical magnetized film.

### <Production Process for CoCrPt Base Sputtering Target>

The production process for the CoCrPt base sputtering target of the present invention includes two processes of the first process and the second process. First, the first process shall be explained in details.

### First Process:

The first process is characterized by comprising:

an A step in which an alloy comprising cobalt and chromium is atomized and then pulverized to thereby obtain a powder (1),
a B step in which cobalt and ceramics are subjected to mechanical alloying to thereby obtain a powder (2),
a C step in which the powder (1) and the powder (2) are mixed with platinum to obtain a powder (3) and
a D step in which the powder (3) is calcined.

### A Step:

First, an alloy comprising cobalt and chromium is atomized in the A step. The alloy used as the raw material has a chromium concentration of usually 35 to 95 atom %, preferably 35 to 68 atom %. This alloy is atomized to thereby obtain a powder.

The atomizing method shall not specifically be restricted and may be any of a water atomizing method, a gas atomizing method, a vacuum atomizing method and a centrifugal atomizing method, and the gas atomizing method is preferred. The tap temperature is usually 1420 to 1800° C., preferably 1420 to 1600° C. When using the gas atomizing method, N₂ gas or Ar gas is usually injected, and Ar gas is preferably injected because of the reasons that oxidation can be inhibited and that spherical powders are obtained. Atomized powders having an average particle diameter of 10 to 600 μm, preferably 10 to 200 μm and more preferably 10 to 80 μm are obtained by atomizing the alloy described above.

Then, the atomized powder thus obtained is pulverized to obtain a powder (1). A pulverizing rate of the above powder (1) is usually 30 to 95%, preferably 50 to 95% and more preferably 80 to 90%. If the pulverizing rate falls in the range described above, the powder (1) can sufficiently be pulverized to fine particles to reduce a size or a production amount of the high chromium-containing particles unevenly distributed in the target, and impurities such as zirconia or carbon which tend to be increased as the pulverizing rate is elevated can suitably be inhibited from being mixed in.

The pulverizing rate means a value α (%) determined by the following equation (i) in employing a microtrac particle diameter (D₉₀), wherein D₉₀(0) is the diameter (D₉₀) before pulverized, and D₉₀(t) is the diameter (D₉₀) after pulverized for t hours.

pulverizing rate α (%)=[(D₉₀(0)−D₉₀(t))/D₉₀(0)]1×100 (i)

The pulverization is carried out by a ball mill in order to obtain the pulverizing rate described above, and high purity zirconia balls and alumina balls can be used as the ball. The high purity zirconia balls are suitably used. The zirconia balls have usually a diameter of 1 to 20 mm. A vessel of the ball mill includes a resin-made vessel, a vessel in which a tabular matter comprising the constituent elements of the target is stuck on a resin and the like.

The rotation speed and the rotation time are determined preferably considering a pulverizing rate of the powder (1) and a mixing amount of the impurities, and, for example, the rotation speed is usually 20 to 80 rpm, preferably 30 to 70 rpm and more preferably 45 to 60 rpm. The rotation time is usually 50 to 150 hours, preferably 12 to 150 hours and more preferably 48 to 150 hours. If the rotation speed and the rotation time fall in the ranges described above, the finer powder (1) is obtained, and a mixing amount of the impurities caused by pulverization can be controlled. Use of the above powder (1) makes it possible to prepare the sputtering target having a higher uniformity and containing less amount of the impurities.

A chromium-containing powder having a microtrac particle diameter (D₉₀) of 50 μm or less may be directly used instead of obtaining the powder (1) as described above to carry out processing in the subsequent steps. A lower limit value of the microtrac particle diameter (D₉₀) shall not specifically be restricted and is preferably 0.05 μm or more. The above chromium-containing powder contains preferably ceramics and the like in addition to cobalt and chromium.

### B Step:

In the B step, cobalt and ceramics are subjected to mechanical alloying to thereby obtain a powder (2). Ceramics is, to be specific, at least one selected from the group consisting of silicon dioxide, titanium dioxide, tantalum pentaoxide, Al₂O₃, MgO CaO, ZrO₂, B₂O₃, Sm₂O₃, HfO₂ and Gd₂O₃, and they may be used alone or in a mixture of two or more kinds thereof. Among them, silicon dioxide is preferred.

When carrying out the mechanical alloying described above, cobalt powder and ceramics powder may be used. When using the cobalt powder, the above powder has a microtrac particle diameter (D₉₀) of usually 0.05 to 100, preferably 0.05 to 10 and more preferably 0.05 to 7 and a microtrac particle diameter (D₅₀) of usually 0.025 to 50, preferably 0.25 to 5. When using the ceramics powder, the above powder has a microtrac particle diameter (D₉₀) of usually 0.05 to 10, preferably 0.05 to 5 and more preferably 0.05 to 3 and a microtrac particle diameter (D₅₀) of usually 0.025 to 50, preferably 0.025 to 5.

A mole ratio of cobalt to ceramics which are used as the raw materials is usually 1/50 to 50/1, preferably 1/20 to 20/1 and more preferably 1/10 to 10/1.

The mechanical alloying is carried out by a ball mill, and high purity zirconia balls and alumina balls can be used as the ball. The high purity zirconia balls are suitably used. The zirconia balls have usually a diameter of 1 to 20 mm. A vessel of the ball mill includes a resin-made vessel, a vessel in which a tabular matter comprising the constituent elements of the target is stuck on a resin and the like. A weight ratio of the total amount of cobalt and ceramics to the weight of the balls is usually 1/5 to 1/100, preferably 1/5 to 1/50. If they fall in the ranges described above, the mechanical alloying can efficiently be carried out.

A rotation speed of the ball mill is usually 20 to 80 rpm, preferably 30 to 70 rpm and more preferably 45 to 60 rpm. The rotation time is usually 5 to 250 hours, preferably 40 to 200 hours and more preferably 120 to 200 hours. If the rotation speed and the rotation time fall in the ranges described above, the powder (2) in which cobalt and ceramics are evenly mixed can be obtained, and use of the above powder (2) makes it possible to prepare the sputtering target having a higher uniformity.

### C Step:

In the C step, the powder (1) and the powder (2) are mixed with platinum to obtain a powder (3). A simple powder of platinum having an average particle diameter of 0.05 to 10 μm is preferably used as platinum. When using the simple powder of platinum, the above powder has a microtrac particle diameter (D₉₀) of usually 0.05 to 100, preferably 0.05 to 10 and more preferably 0.05 to 2 and a microtrac particle diameter (D₅₀) of usually 0.025 to 5, preferably 0.025 to 0.5 and more preferably 0.025 to 0.25.

The mixing method shall not specifically be restricted, and blender mill mixing is suited. In the production process of the present invention, platinum is mixed immediately before the calcining step (D step) of the subsequent step without atomizing platinum, and therefore a yield of platinum can inevitably be enhanced.

In this step, cobalt may be mixed at the same time in addition to platinum. The same powder as the cobalt powder which can be used in the B step described above is preferably used as cobalt used in this case.

An E step in which the powder (3) is sized may be provided between the C step and the D step, that is, before transferring to the D step. A vibrating sieve is used for sizing. Sizing makes it possible to enhance further more a uniformity of the powder (3).

### D Step:

In the D step, the powder (3) is calcined. Calcining is carried out usually under inert gas atmosphere or vacuum atmosphere, and it is carried out preferably under inert gas atmosphere. The calcining temperature is usually 900 to 1500° C., preferably 1000 to 1400° C. and more preferably 1100 to 1300° C. The pressure in calcining is usually 5 to 100 MPa, preferably 5 to 50 MPa and more preferably 10 to 30 MPa.

The above calcining is carried out more preferably by pressure sintering. Pressure sintering includes a hot press method, an HP method and an HIP method. The calcining is carried out under the same calcining conditions as described above.

A sintered matter obtained through the D step in the manner described above is mechanically processed by a conventional method to thereby prepare a CoCrPt base sputtering target having a desired dimension.

### Second Process:

The second process for preparing the CoCrPt base sputtering target of the present invention is characterized by comprising:

an F step in which an alloy of cobalt and chromium and ceramics are subjected to mechanical alloying to thereby obtain a powder (4),
a G step in which the powder (4) is mixed with platinum to obtain a powder (5) and
a H step in which the powder (5) is calcined.

### F Step:

In the F step, the alloy of cobalt and chromium and ceramics are subjected to mechanical alloying to thereby obtain the powder (4). The alloy of cobalt and chromium is preferably atomized. The alloy used as the raw material has a chromium concentration of usually 35 to 95 atom %, preferably 35 to 68 atom %. This alloy is atomized to thereby obtain a powder.

The atomizing method shall not specifically be restricted and may be any of a water atomizing method, a gas atomizing method, a vacuum atomizing method and a centrifugal atomizing method, and the gas atomizing method is preferred. The tap temperature is usually 1420 to 1800° C., preferably 1420 to 1600° C. When using the gas atomizing method, N₂ gas or Ar gas is usually injected, and Ar gas is preferably injected because of the reasons that oxidation can be inhibited and that spherical powders are obtained. Atomized powders having an average particle diameter of 10 to 600 μm, preferably 10 to 200 μm and more preferably 10 to 80 μm are obtained by atomizing the alloy described above.

The alloy of cobalt and chromium or the atomized powders thereof and ceramics are subjected to mechanical alloying to obtain the powder (4). The ceramics used is the same as the ceramics used in the B step.

The mechanical alloying is carried out by a ball mill, and high purity zirconia balls and alumina balls can be used as the ball. The high purity zirconia balls are suitably used. The zirconia balls have usually a diameter of 1 to 20 mm. A vessel of the ball mill includes a resin-made vessel, a vessel in which a tabular matter comprising the constituent elements of the target is stuck on a resin and the like. A weight ratio of the total amount of cobalt and ceramics to the weight of the balls is usually 1/5 to 1/100, preferably 1/5 to 1/50. If they fall in the ranges described above, the mechanical alloying can efficiently be carried out.

A rotation speed of the ball mill is usually 20 to 80 rpm, preferably 30 to 70 rpm and more preferably 45 to 60 rpm. The rotation time is usually 5 to 250 hours, preferably 40 to 200 hours and more preferably 120 to 200 hours. If the rotation speed and the rotation time fall in the ranges described above, the powder (4) in which the atomized powders and ceramics are suitably pulverized and evenly mixed is obtained, and use of the above powder (4) makes it possible to prepare the sputtering target having a higher uniformity.

A pulverizing rate of the above powder (4) is usually 30 to 95%, preferably 50 to 95% and more preferably 80 to 90%. If the pulverizing rate falls in the range described above, the powder (4) can sufficiently be pulverized to fine particles to reduce a size or a production amount of the high chromium-containing particles unevenly distributed in the target, and impurities such as zirconia or carbon which tend to be increased as the pulverizing rate is elevated can suitably be inhibited from being mixed in.

The above pulverizing rate means the same as the pulverizing rate in the A step.

Further, a chromium-containing powder having a microtrac particle diameter (D₉₀) of 50 μm or less may be directly used instead of obtaining the powder (4) as described above to carry out processing in the subsequent steps. A lower limit value of the microtrac particle diameter (D₉₀) shall not specifically be restricted and is preferably 0.05 μm or more. The above chromium-containing powder contains preferably ceramics and the like in addition to cobalt and chromium.

### G Step:

In the G step, the powder (4) is mixed with platinum to obtain the powder (5). The same simple powder of platinum as the platinum powder used in the C step is preferably used as platinum. The mixing method shall not specifically be restricted, and blender mill mixing is suited. In the production process of the present invention, platinum is mixed immediately before the calcining step (H step) of the subsequent step without atomizing platinum, and therefore a yield of platinum can inevitably be enhanced.

An I step in which the powder (3) is sized may be provided between the G step and the H step, that is, before transferring to the H step. A vibrating sieve is used for sizing. Sizing makes it possible to enhance further more a uniformity of the powder (5).

### H Step:

In the H step, the powder (5) is calcined. Calcining is carried out usually under inert gas atmosphere or vacuum atmosphere, and it is carried out preferably under inert gas atmosphere. The calcining temperature is usually 900 to 1500° C., preferably 1000 to 1400° C. and more preferably 1100 to 1300° C. The pressure in calcining is usually 5 to 100 MPa, preferably 5 to 50 MPa and more preferably 10 to 30 MPa. The above calcining is carried out preferably by pressure sintering. Pressure sintering includes a hot press method, an HP method and an HIP method. The calcining is carried out under the same calcining conditions as described above.

A sintered matter obtained through the H step in the manner described above is mechanically processed by a conventional method to thereby prepare a CoCrPt base sputtering target having a desired dimension.

As described above, the production process for the CoCrPt base sputtering target of the present invention includes two processes of the first process and the second process, and the second process is preferably used in order to reduce more an amount of impurities such as zirconium and carbon in pulverizing and mechanical alloying.

### EXAMPLES

The present invention shall specifically be explained below with reference to examples, but the present invention shall not be restricted by them.

### Example 1

### Production of CoCrPt Base Sputtering Target According to the First Process

An alloy of CO₆₀Cr₄₀ 1.5 kg was gas-atomized while injecting an Ar gas of 50 kg/cm² at a tap temperature of 1650° C. (measured by a radiation thermometer) by means of a microminiature gas atomizing equipment (manufactured by Nissin Giken Co., Ltd.) to obtain a powder. The powder thus obtained was a spherical powder having an average particle diameter of 150 μm or less.

Then, the powder obtained above was pulverized under air atmosphere at a weight ratio of the ball to the powder set to 20:1, a rotation speed of 50 rpm and a rotation time of 6 hours by means of a zirconia ball mill to obtain a powder (1).

A Co powder (manufactured by Soekawa Chemical Co., Ltd., average particle diameter: about 2 mm, D₉₀: 6.71, D₅₀: 4.29) and a SiO₂ powder (manufactured by Admatech Co., Ltd., average particle diameter: about 2 μm, D₉₀: 2.87, D₅₀: 1.52) were subjected to mechanical alloying so that a weight ratio thereof was 1:2. A resin-made vessel having a volume of 2 liter was charged with zirconia-made balls of 5 mmφ and the Co powder and SiO₂ powder described above, and mechanical alloying was carried out at a weight ratio of the balls to the above powders set to 1:40, a rotation speed of 50 rpm and a rotation time of 120 hours to obtain a powder (2).

A Pt powder (manufactured by Tanaka Kikinzoku Kogyo K.K., average particle diameter: about 0.5 μm, D₉₀: 1.78, D₅₀: 0.58) and the same Co powder as described above were further added to the powder (1) and the powder (2) obtained above and mixed so that a composition ratio thereof was set to CO₆₄Cr₁₀Pt₁₆(SiO₂)₁₀ to obtain a powder (3). A ball mill was used for mixing.

The powder (3) thus obtained was further sized by means of a vibration sieve.

Then, the powder (3) was put in a molding die and subjected to hot press at a sintering temperature of 1150° C., a sintering time of 1 hour and a surface pressure of 200 kgf/cm² under Ar atmosphere. The sintered matter thus obtained was subjected to cutting work to obtain a sputtering target of 4 inchφ.

### Examples 2 to 4

Sputtering targets were obtained by the same process as in Example 1, except that the rotation time was set to 48 hours, 144 hours and 192 hours respectively in the pulverizing step using the zirconia ball mill for obtaining the powder (1).

### Comparative Examples 1 to 2

Sputtering targets were obtained by the same process as in Example 1, except that the rotation time was set to 0 hour or 3 hours in the pulverizing step using the zirconia ball mill for obtaining the powder (1).

### Example 5

### Production of CoCrPt Base Sputtering Target According to the Second Process

An alloy of CO₆₀Cr₄₀ 2 kg was gas-atomized while injecting an Ar gas of 50 kg/cm² at a tap temperature of 1650° C. (measured by a radiation thermometer) by means of a microminiature gas atomizing equipment (manufactured by Nissin Giken Co., Ltd.) to obtain a powder. The powder thus obtained was a spherical powder having an average particle diameter of 150 μm or less.

Then, the powder obtained above and the same powder as the SiO₂ powder used in Example 1 were used and subjected to mechanical alloying under air atmosphere at a weight ratio of the ball to the powder set to 20:1, a rotation speed of 50 rpm and a rotation time of 192 hours by means of a zirconia ball mill to obtain a powder (4).

The same powders as the Pt powder and the Co powder each used in Example 1 were further added to the powder (4) obtained above and mixed so that a composition ratio thereof was set to CO₆₄Cr₁₀Pt₁₆(SiO₂)₁₀ to obtain a powder (5). A ball mill was used for mixing.

The powder (5) thus obtained was further sized by means of a vibration sieve.

Then, the powder (5) was put in a molding die and subjected to hot press at a sintering temperature of 1150° C., a sintering time of 1 hour and a surface pressure of 200 kgf/cm² under Ar atmosphere. The sintered matter thus obtained was subjected to cutting work to obtain a sputtering target of 4 inchφ.

### Evaluation:

The sputtering targets obtained in Examples 1 to 5 and Comparative Examples 1 to 2 were used and evaluated by the following methods.

### Pulverizing Rate:

The microtrac particle diameters (D₉₀) were used to measure the values of D₉₀ before pulverization and D₉₀ after pulverization in the first process and measure the values of D₉₀ before mechanical alloying and D₉₀ after mechanical alloying in the second process, and the pulverizing rate was determined form the above values.

### Number of High Chromium-Containing Particles:

A scanning type analytical electron microscope (manufactured by JEOL DATUM LTD.) was used to observe the surface of the sputtering targets prepared in Examples 1 to 5 and Comparative Examples 1 to 2, and the number of the high chromium-containing particles having a full diameter of 15 μm or more in a viewing field of 0.6×0.5 mm² was measured.

### Cr Concentration in High Chromium-Containing Particles:

The area described above in which the high chromium-containing particles were observed was magnified by 10000 times to carry out simple quantitative face analysis of chromium in a viewing field of 20×10 μm, wherein five points were optionally taken to measure Cr concentrations in the respective points, and an average value thereof was determined to obtain a Cr concentration of the high chromium-containing particles.

### Arcing Frequency:

A sheet type magnetron sputtering equipment was used to measure an arcing frequency in preparing the magnetic recording film at an Ar gas pressure of 0.5 Pa and an input electric power of 5 W/cm².

An arcing counter (μ Arc Monitor, manufactured by Landmark Technology Co., Ltd.) was used for measuring the arcing frequency, and the arcing frequency to an integrated input electric power (integrated electric energy per target unit area input in sputtering) of 20 W/cm² was determined at a detection mode of energy, an arc detection pressure of 100 V, a maximum-medium energy boundary of 50 mJ and a hard arc minimum time of 100 μa.

### Dropping Number of High Chromium-Containing Particles:

A scanning type analytical electron microscope (manufactured by JEOL DATUM LTD.) was used to observe the surface of the sputtering target after preparing the magnetic recording film described above, and the number of the dropping traces of the high chromium-containing particles having a full diameter of 10 μm or more in a viewing field of 1.0×1.0 mm² was measured.

### Coercive Force Dispersibility:

Films were formed on a glass substrate in an order of Co—Nb—Zr, Ru and magnetic films obtained from the targets prepared in Examples 1 to 5 and Comparative Examples 1 to 2 under the same conditions as the film-forming conditions in preparing the magnetic recording films described above to prepare a multilayer film. A coercive force of the multilayer film thus obtained in a circumferential direction was measured to determine a difference in a maximum value and a minimum value of the coercive forces as a coercive force dispersibility (G).

### Mixing Amounts of Zr and C:

Measured were the mixing amounts of Zr and C which were impurities mixed in the pulverizing step in the first process or the mechanical alloying step in the second process. The mixing amount of Zr was measured by means of an ICP emission spectrophotometer SP300 (manufactured by Seiko Instruments Inc.). The mixing amount of C was measured by means of a carbon-sulfur analytical equipment EMIA-521 (manufactured by HORIBA Ltd.) by an infrared absorption method after burning the powder in oxygen flow.

The results described above are shown in Table 1.

TABLE 1
Target evaluation

| | | | | | Cr concentration |
|---|---|---|---|---|---|
| Arcing | | Coercive force | Cr maximum | Number of high | (atom %) of high |
| frequency | Cr dropping | dispersibility | full diameter | chromium-containing | chromium-containing |
| (times) | number | (G) | (μm) | particles | particles |
| 10 | 53 | 105 | 40 | 19 | 16.3 |
| 2 | 34 | 100 | — | — | — |
| 1 | 30 | 84 | — | — | — |
| 2 | 31 | 98 | 30 | 15 | 15.4 |
| 1 | 2 | 82 | 20 | 0 | — |
| 78 | 135 | 225 | 70 | 37 | 21.3 |
| 53 | 68 | 168 | — | — | — |

1. A CoCrPt base sputtering target characterized by containing cobalt, chromium, ceramics and platinum, wherein high chromium-containing particles containing a chromium atom at a high concentration which are unevenly distributed in the above sputtering target have a maximum full diameter of 40 μm or less.

2. The CoCrPt base sputtering target as described in claim 1, wherein high chromium-containing particles having a full diameter of 15 μm or more account for 20 particles or less in a viewing field of 0.6×0.5 mm² measured on the surface of the above sputtering target under a scanning type analytical electron microscope.

3. A production process for a CoCrPt base sputtering target characterized by comprising;
an A step in which an alloy comprising cobalt and chromium is atomized and then pulverized to thereby obtain a powder (1),
a B step in which cobalt and ceramics are subjected to mechanical alloying to thereby obtain a powder (2),
a C step in which the powder (1) and the powder (2) are mixed with platinum to obtain a powder (3) and
a D step in which the powder (3) is calcined.

4. The production process for a CoCrPt base sputtering target as described in claim 3, wherein the C step is a step in which the powder (1) and the powder (2) are mixed with platinum and cobalt to obtain the powder (3).

5. The production process for a CoCrPt base sputtering target as described in claim 3, wherein the D step is a step in which the powder (3) is calcined by pressure sintering.

6. The production process for a CoCrPt base sputtering target as described in claim 3, wherein an E step in which the powder (3) is sized is provided between the C step and the D step.

7. The production process for a CoCrPt base sputtering target as described in claim 3, wherein a chromium-containing powder having a microtrac particle diameter (D₉₀) of 50 μm or less is used as the powder (1) in the A step.

8. A production process for a CoCrPt base sputtering target characterized by comprising:
an F step in which an alloy of cobalt and chromium and ceramics are subjected to mechanical alloying to thereby obtain a powder (4),
a G step in which the powder (4) is mixed with platinum to obtain a powder (5) and
a H step in which the powder (5) is calcined.

9. The production process for a CoCrPt base sputtering target as described in claim 8, wherein the G step is a step in which the powder (4) is mixed with platinum and cobalt to obtain the powder (5).

10. The production process for a CoCrPt base sputtering target as described in claim 8, wherein the H step is a step in which the powder (D) is calcined by pressure sintering.

11. The production process for a CoCrPt base sputtering target as described in claim 8, wherein an I step in which the powder (5) is sized is provided between the G step and the H step.

12. The production process for a CoCrPt base sputtering target as described in claim 8, wherein a chromium-containing powder having a microtrac particle diameter (D₉₀) of 50 μm or less is used as the powder (4) in the F step.
